(19) United States
(12) Patent Application Publication
(10) Pub. No.: US 2015/0060125 A1
(43) Pub. Date: Mar. 5, 2015

(54) TOUCH PANEL

(71) Applicant: WINTEK CORPORATION, Taichung City (TW)

(72) Inventors: David E. Stevenson, Dexter, MI (US); Siang-Lin Huang, Taichung City (TW); Chia-Chi Chen, Taichung City (TW); Kuo-Chang Su, Taichung City (TW)

(21) Appl. No.: 14/476,756

(22) Filed: Sep. 4, 2014

(30) Foreign Application Priority Data
Sep. 5, 2013 (TW) 102216721

(51) Int. Cl. H05K 1/02; H05K 1/09; H05K 1/03

(52) U.S. Cl. CPC H05K 1/0259; H05K 1/03; H05K 1/09; H05K 1/0296; H05K 2201/10204
USPC 174/261

(57) ABSTRACT

A touch panel includes a substrate, a plurality of first axis electrodes, a plurality of second axis electrodes and a first insulation layer. Each first axis electrode includes a plurality of first sub-electrodes and a plurality of first connection parts disposed between two adjacent first sub-electrodes. The first sub-electrodes and the first connection parts are monolithically formed. Each second axis electrode includes a plurality of second sub-electrodes and a plurality of second connection parts disposed between two adjacent second sub-electrodes. The second sub-electrodes and the second connection parts are monolithically formed. The first sub-electrodes and the second sub-electrodes are disposed on an identical surface. The first insulation layer is disposed on and completely covers the first axis electrodes. The first insulation layer is partially disposed between the first connection part and the second connection part. The first axis electrodes are disposed between the first insulation layer and the substrate.

### BACKGROUND OF THE INVENTION

1. Field of the Invention

The present invention generally relates to a touch panel, and more particularly, to a touch panel including an axis electrode formed monolithically.

2. Description of the Prior Art

In recent years, touch sensing technologies have developed flourishingly. There are many diverse technologies of touch panel, such as the resistance touch technology, the capacitive touch technology and the optical touch technology which are the main touch technologies in use. The capacitive touch technology has become the mainstream touch technology for the high-end and the mid-end consumer electronics, because the capacitive touch panel has advantages such as high precision, multi-touch property, better endurance, and higher touch resolution. As shown in FIG. 1 and FIG. 2, in the conventional capacitive touch panel 100, a first axis electrode 140X and a second axis electrode 140Y, which are used to perform touch sensing functions, are disposed on a substrate 110 and extend toward different directions respectively. In the first axis electrode 140X, two adjacent sub-electrodes 140S are electrically connected to each other via a connection line 120. The connection line 120 is formed on the substrate first, and an insulation block 130 is then formed on the connection line 120 and partially exposes the connection line 120. Afterward the second axis electrode 140Y and the sub-electrodes 140S are formed simultaneously, and the sub-electrodes 140S can contact the connection line 120 exposed by the insulation block 130 for being electrically connected to each other. However, a contact interface between the sub-electrodes 140S and the connection line 120 is formed no matter whether the materials of the sub-electrodes 140 and the connection line 120 are different or identical. The resistance at the contact interface will influence the electrostatic discharge protection ability. In other words, electrostatic discharge tends to occur at the contact interface between the sub-electrodes 140S and the connection line 120, and the reliability of the capacitive touch panel 100 may be affected. In addition, because the connection line 120 has to be partially exposed by the insulation block 130, the connection line 120 may be damaged by the related manufacturing process of the insulation block 130. For example, the developer used in the photolithography process of the insulation block 130 may damage the connection line 120, the manufacturing yield may be affected, and the variability of materials and processes may be limited accordingly.

### SUMMARY OF THE INVENTION

It is one of the objectives of the present invention to provide a touch panel. A monolithically formed first axis electrode and a monolithically formed second axis electrode are disposed and cross each other so as to enhance the electrostatic discharge protection ability in each axis electrode. Additionally, a first insulation layer is used to completely cover the first axis electrode. First sub-electrodes of the first axis electrode and second sub-electrodes of the second axis electrode may be disposed on the same surface by modifying the distribution condition of the first insulation layer.

To achieve the purposes described above, a preferred embodiment of the present invention provides a touch panel. The touch panel includes a substrate, a plurality of first axis electrodes, a plurality of second axis electrodes and a first insulation layer. The first axis electrodes are disposed on the substrate. Each of the first axis electrodes extends along a first direction, and each of the first axis electrodes includes a plurality of first sub-electrodes and a plurality of first connection parts. Each of the first connection parts is disposed between two adjacent first sub-electrodes so as to electrically connect the first sub-electrodes. Each of the first connection parts and two adjacent first sub-electrodes are monolithically formed. The second axis electrodes are disposed on the substrate. Each of the second axis electrodes extends along a second direction, the second direction crosses the first direction, and each of the second axis electrodes includes a plurality of second sub-electrodes and a plurality of second connection parts. Each of the second connection parts is disposed between two adjacent second sub-electrodes so as to electrically connect the second sub-electrodes. Each of the second connection parts and two adjacent second sub-electrodes are monolithically formed. The first sub-electrodes and the second sub-electrodes are disposed on an identical surface. The first insulation layer is disposed on the first axis electrodes and completely covers the first axis electrodes along a vertical projective direction perpendicular to the substrate. The first insulation layer is partially disposed between each first connection part and each second connection part so as to electrically insulate the first axis electrodes from the second axis electrodes, and the first axis electrodes are disposed between the first insulation layer and the substrate.

In the touch panel of the present invention, the first axis electrode and the second axis electrode extend along different direction. Each of the first axis electrodes is monolithically formed, and each of the second axis electrodes is monolithically formed so as to enhance the electrostatic discharge protection ability. In addition, the first insulation layer completely covering the first axis electrodes is used to keep the first axis electrodes from being damaged by the manufacturing processes of the first insulation layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a conventional capacitive touch panel.

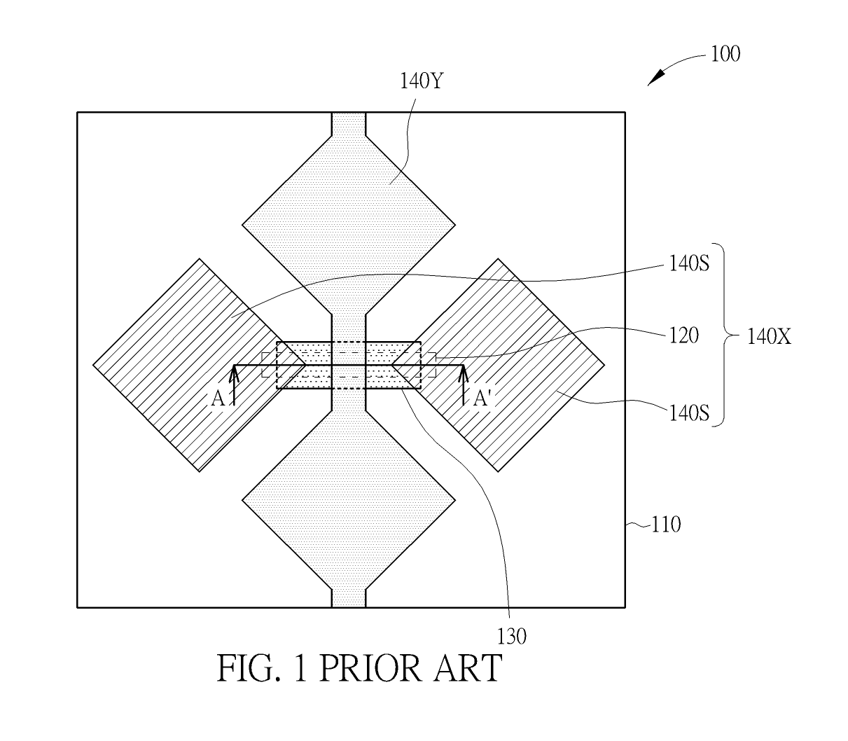

FIG. 2 is a schematic cross-sectional diagram taken along a line A-A′ in FIG. 1.

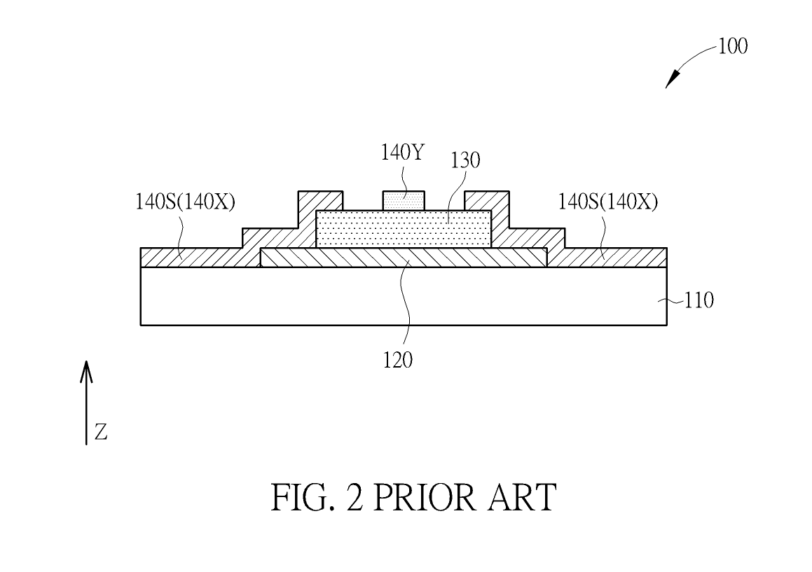

FIG. 3 is a schematic diagram illustrating a touch panel according to a first embodiment of the present invention.

FIG. 4 is a schematic cross-sectional diagram taken along a line B-B′ in FIG. 3.

FIG. 5 is a schematic diagram illustrating a touch panel according to a second embodiment of the present invention.

FIG. 6 is a schematic cross-sectional diagram taken along a line C-C′ in FIG. 5.

FIG. 7 is a schematic diagram illustrating a touch panel according to a third embodiment of the present invention.

FIG. 8 is a schematic cross-sectional diagram taken along a line D-D′ in FIG. 7.

FIG. 9 is a schematic diagram illustrating a touch panel according to a fourth embodiment of the present invention.

FIG. 10 is a schematic cross-sectional diagram taken along a line E-E′ in FIG. 9.

FIG. 11 is a schematic diagram illustrating a touch panel according to a fifth embodiment of the present invention.

FIG. 12 is a schematic diagram illustrating a touch panel according to a sixth embodiment of the present invention.

FIG. 13 is a schematic diagram illustrating a touch panel according to a seventh embodiment of the present invention.

FIG. 14 is a schematic cross-sectional diagram taken along a line F-F′ in FIG. 13.

FIG. 15 is a schematic diagram illustrating a touch panel according to an eighth embodiment of the present invention.

### DETAILED DESCRIPTION

To provide a better understanding of the present invention to the skilled users in the technology of the present invention, preferred embodiments will be detailed as follows. The preferred embodiments of the present invention are illustrated in the accompanying drawings with numbered elements to elaborate the contents and effects to be achieved.

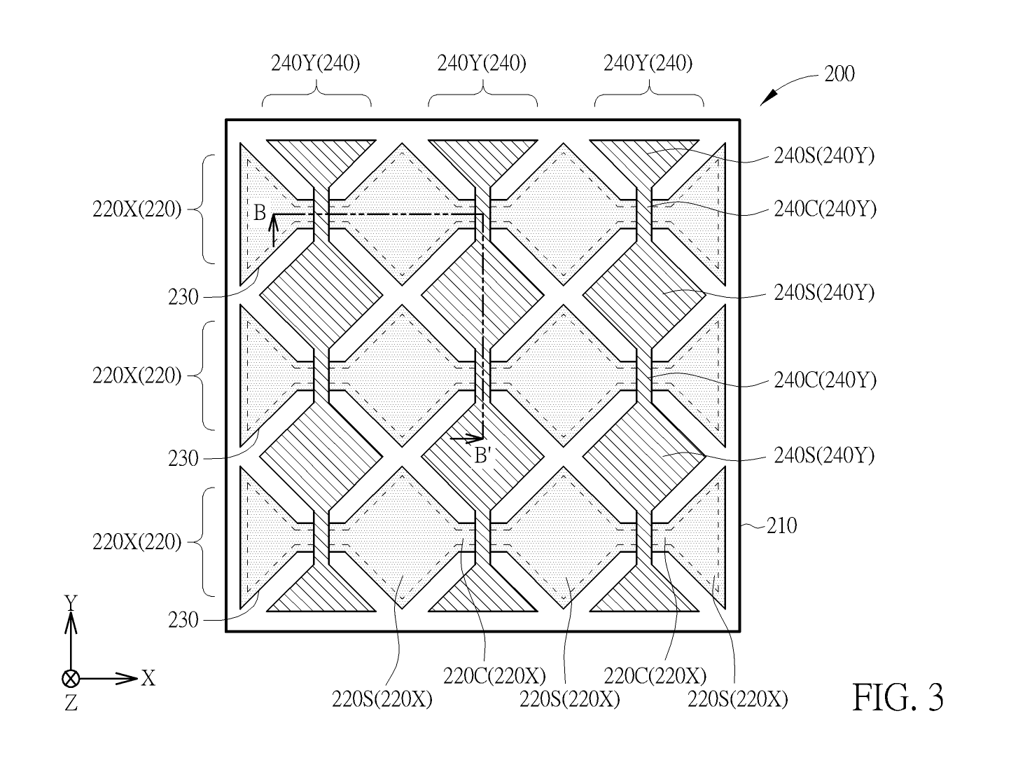

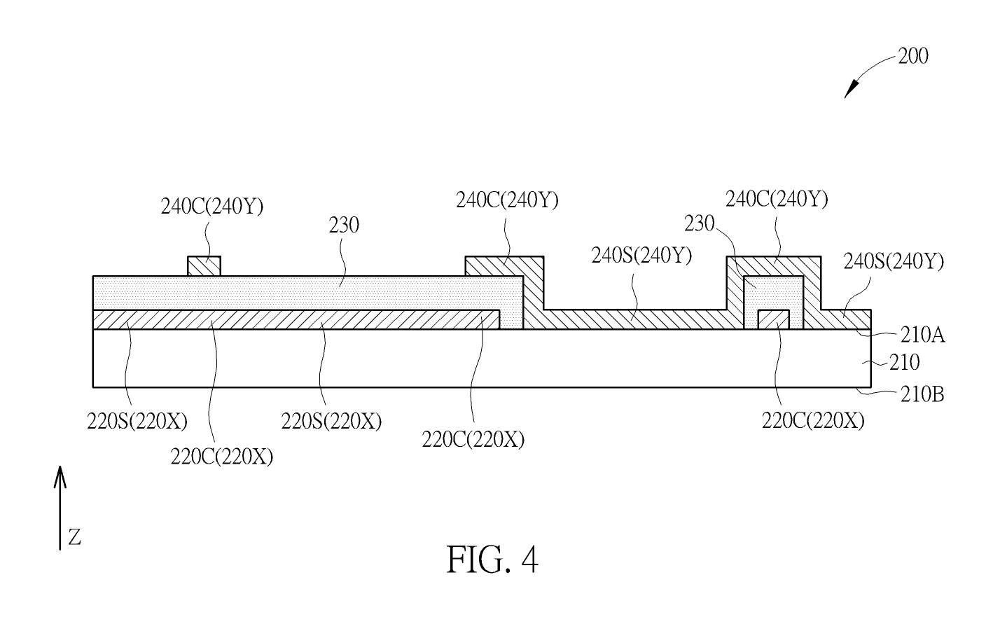

Please refer to FIG. 3 and FIG. 4. FIG. 3 is a schematic diagram illustrating a touch panel according to a first embodiment of the present invention. FIG. 4 is a schematic cross-sectional diagram taken along a line B-B′ in FIG. 3. Please note that the figures are only for illustration and the figures may not be to scale. The scale may be further modified according to different design considerations. As shown in FIG. 3 and FIG. 4, a touch panel 200 is provided in this embodiment. The touch panel 200 includes a substrate 210, a plurality of first axis electrodes 220X, a plurality of second axis electrodes 240Y and a first insulation layer 230. The first axis electrodes 220X are disposed on the substrate 210. Each of the first axis electrodes 220X extends along a first direction X. Each of the first axis electrodes 220X includes a plurality of first sub-electrodes 220S and a plurality of first connection parts 220C. Each of the first connection parts 220C is disposed between two adjacent first sub-electrodes 220S so as to electrically connect the first sub-electrodes 220S. Each of the first connection parts 220C and two adjacent first sub-electrodes 220S are monolithically formed. In other words, the first connection parts 220C and the first sub-electrodes 220S within one identical first axis electrode 220X are monolithically formed. For example, the first axis electrodes 220X may be formed by patterning a first conductive layer 220, and the first connection parts 220C and the first sub-electrodes 220S are formed simultaneously and monolithically without any interfaces between the first connection part 220C and the first sub-electrode 220S. Additionally, the second axis electrodes 240Y are disposed on the substrate 210. Each of the second axis electrodes 240Y extends along a second direction Y, and the second direction Y crosses the first direction X. The first direction X is substantially perpendicular to the second direction Y preferably, but not limited thereto. Each of the second axis electrodes 240Y includes a plurality of second sub-electrodes 240S and a plurality of second connection parts 240C. Each of the second connection parts 240C is disposed between two adjacent second sub-electrodes 240S so as to electrically connect the second sub-electrodes 240S. Each of the second connection parts 240C and two adjacent second sub-electrodes 240S are monolithically formed. In other words, the second connection parts 240C and the second sub-electrodes 240S within one identical second axis electrode 240Y are monolithically formed. For example, the second axis electrodes 240Y may be formed by patterning a second conductive layer 240, and the second connection parts 240C and the second sub-electrodes 240S are formed simultaneously and monolithically without any interfaces between the second connection part 240C and the second sub-electrode 240S. In addition, a width of each first sub-electrode 220S along the second direction Y is wider than a width of each first connection part 220C along the second direction Y, and a width of each second sub-electrode 240S along the first direction X is wider than a width of each second connection part 240C along the first direction X. By the design described above, the resistance issue at the interface between the sub-electrodes and the connection parts may be avoided, the electrostatic discharge protection ability of each axis electrode may be enhanced, and the reliability of the touch panel 200 may be improved accordingly.

In this embodiment, the first sub-electrodes 220S and the second sub-electrodes 240S are disposed on one identical surface. Specifically, the first sub-electrodes 220S and the second sub-electrodes 240S are disposed on a first surface 210A of the substrate 210, and a second surface 210B opposite to the first surface 210A may be a touch operation surface, but not limited thereto. It is worth noting that other film layers, such as inorganic buffer layers (silicon oxide for example), may be disposed between the substrate 210 and the first sub-electrodes 220S and/or disposed between the substrate 210 and the second sub-electrodes 240S. In addition, the first insulation layer 230 is disposed on the first axis electrodes 220X and completely covers the first axis electrodes 220X along a vertical projective direction Z perpendicular to the substrate 210. In other words, the first insulation layer 230 covers edges of each first axis electrode 220X. The first insulation layer 230 is partially disposed between each first connection part 220C and each second connection part 240C so as to electrically insulate the first axis electrodes 220X from the second axis electrodes 240Y. The first axis electrodes 220X are disposed between the first insulation layer 230 and the substrate 210. In other words, in a manufacturing method of the touch panel 200 in this embodiment, the first conductive layer 220 may be formed on the substrate 210 first, and the first axis electrodes 220X may then be formed by patterning the first conductive layer 220. Subsequently, the first insulation layer 230 is formed to completely cover the first axis electrodes 220X, the second conductive layer 240 is then formed on the first insulation layer 230 and the substrate 210, and the second axis electrodes 240Y are then formed by patterning the second conductive layer 240. In this embodiment, the first conductive layer 220 and the second conductive layer 240 may include a transparent conductive material such as indium tin oxide (ITO), indium zinc oxide (IZO), aluminum zinc oxide (AZO) and nano metal wire, or other appropriate opaque conductive materials such as metal material. The metal material mentioned above may include silver (Ag), aluminum (Al), copper (Cu), magnesium (Mg), molybdenum (Mo), a composite layer of the above-mentioned materials, or an alloy of the above-mentioned materials, but not limited thereto. Additionally, the structures of the first conductive layer 220 and the second conductive layer 240 may be a thin film or a mesh. For example, the first conductive layer 220 and the second conductive layer 240 may be ITO thin films or metal mesh. The metal mesh may be consisted of a plurality of fine metal lines, and a line width of the fine metal line may range between 1 micrometer and 30 micrometers. In the metal mesh electrodes, an aperture between the fine metal lines is much larger than the width of the fine metal line, and the light transmittance of the metal mesh electrode may be higher than 75%. In addition, the substrate 210 may include a rigid substrate or a flexible substrate. For example, the substrate 210 may include a glass substrate, a sapphire, a rigid cover lens, a plastic substrate, a flexible cover lens, a flexible plastic substrate, a thin glass substrate or a substrate of a display device. The substrate of the display device may be a color filter substrate of a liquid crystal display device or an encapsulation plate of an organic light emitting display device, but not limited thereto. In other words, the first axis electrodes 220X and the second axis electrodes 240Y in this embodiment may include transparent materials or metal mesh preferably so as to integrate the touch panel 200 with a display device or combine the touch panel 200 and a display device, but not limited thereto.

It is worth noting that, in this embodiment, an outline of the first insulation layer 230 is the same as an outline of the first axis electrodes 220X preferably, and a shape of the first insulation layer 230 is the same as a shape of the first axis electrodes 220X preferably. The first insulation layer 230 encompasses the first axis electrodes 220X so as to keep the first axis electrodes 220X from being damaged by the manufacturing processes of the first insulation layer 230. For example, the developer used in the photolithography process of the first insulation layer 230 may damage the first axis electrodes 220X if the first axis electrodes are not covered by the first insulation layer 230. However, in other embodiments of the present invention, the first insulation layer 230 in other shapes may also be used to encompass the first axis electrodes 220X. The first insulation layer 230 may include single layer or multiple layer structures formed by inorganic materials, such as silicon nitride, silicon oxide and silicon oxynitride, organic materials, such as acrylic resin, or other appropriate materials. In this embodiment, a refractive index of the first axis electrodes 220X is higher than a refractive index of the first insulation layer 230 and a refractive index of the substrate 210 preferably so as to generate refractive index matching effect for lowering the pattern visibility of the first axis electrodes 220X, but not limited thereto.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

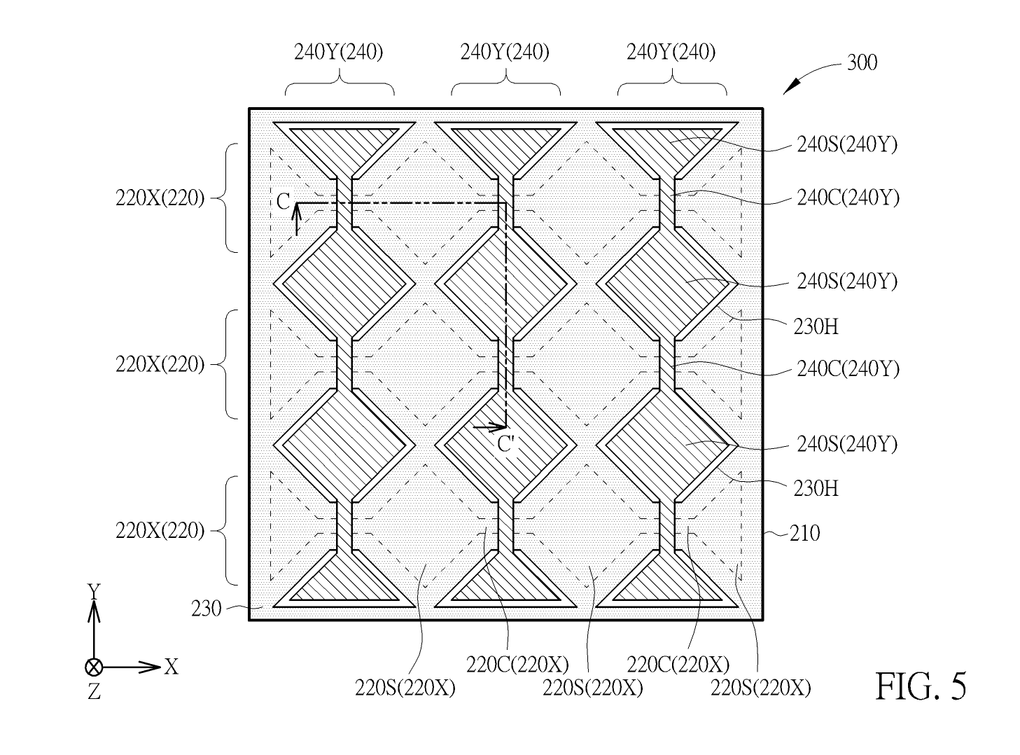

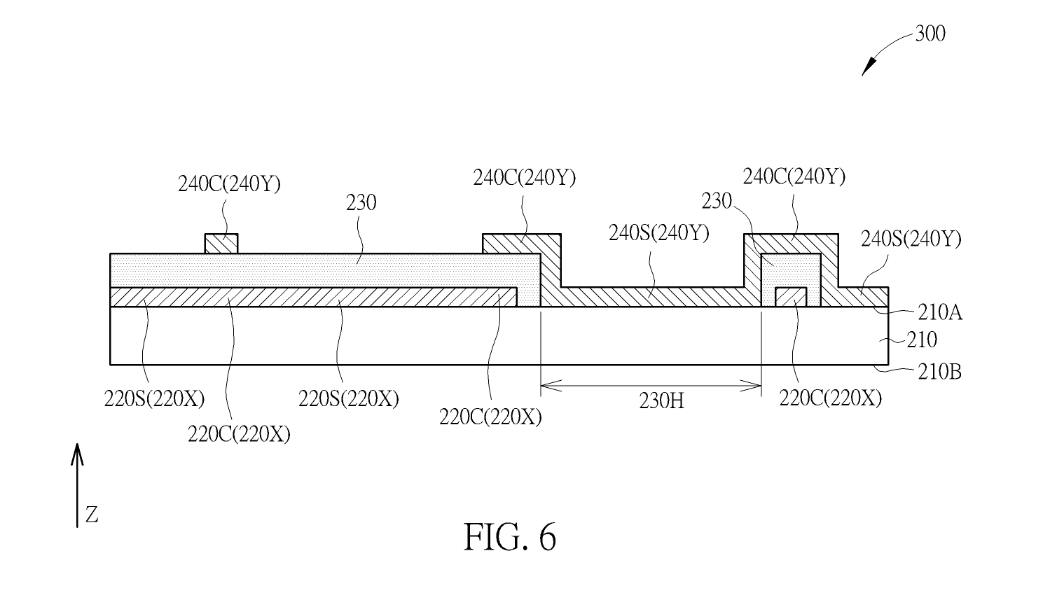

Please refer to FIG. 5 and FIG. 6. FIG. 5 is a schematic diagram illustrating a touch panel 300 according to a second embodiment of the present invention. FIG. 6 is a schematic cross-sectional diagram taken along a line C-C′ in FIG. 5. As shown in FIG. 5 and FIG. 6, the difference between the touch panel 300 in this embodiment and the touch panel in the first embodiment is that, in the touch panel 300, the first insulation layer 230 has a plurality of openings 230H, and each of the second sub-electrodes 240S is disposed in one of the openings 230H correspondingly. In other words, the first insulation layer 230 completely covers the first axis electrodes 220X along the vertical projective direction Z and has a plurality of openings 230H disposed at regions without first axis electrodes 220X on the substrate 210 so as to partially expose the substrate 210. Each of the second sub-electrodes 240S is disposed in one of the openings 230H correspondingly, and the first sub-electrodes 220S and the second sub-electrodes 240S may then be disposed on the identical surface.

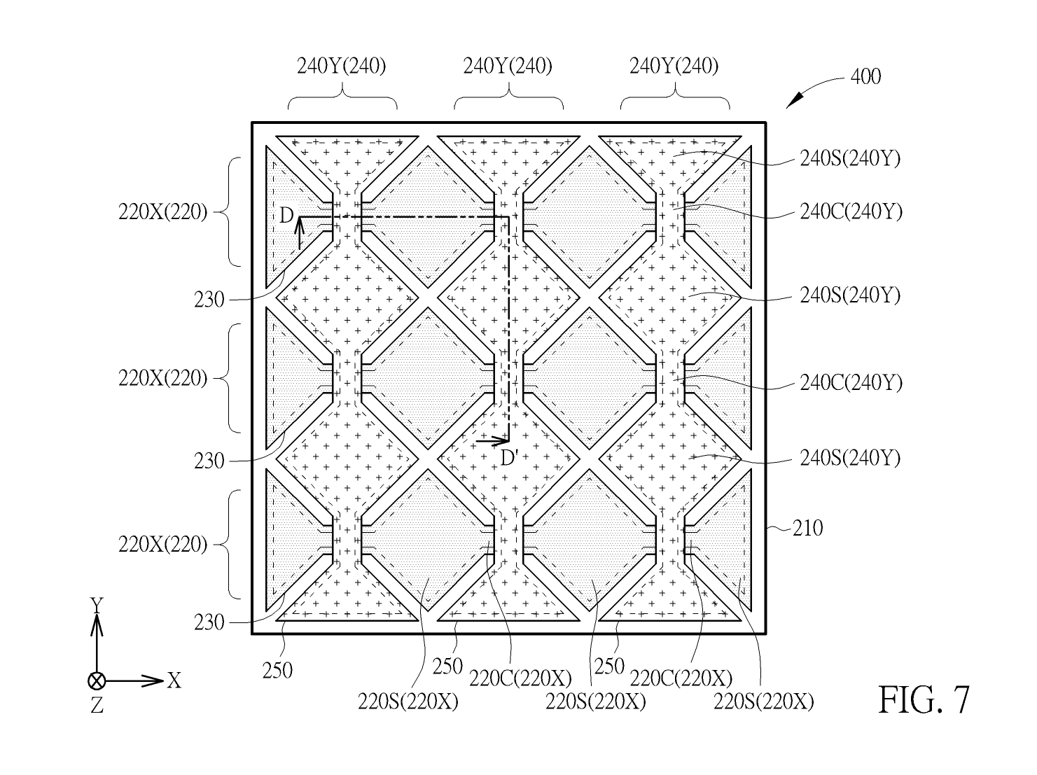

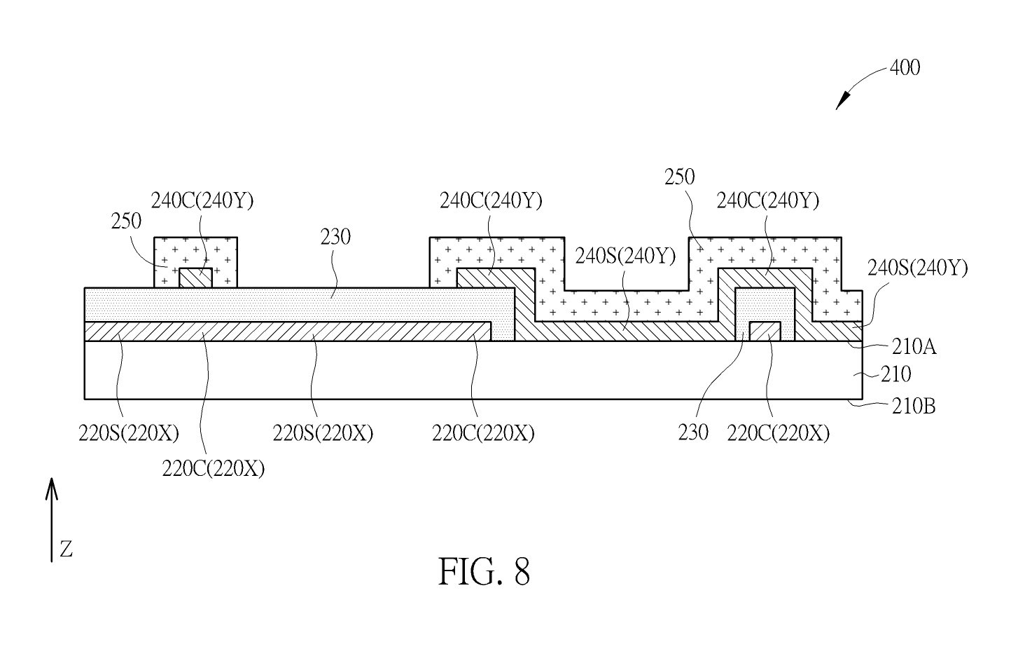

Please refer to FIG. 7 and FIG. 8. FIG. 7 is a schematic diagram illustrating a touch panel 400 according to a third embodiment of the present invention. FIG. 8 is a schematic cross-sectional diagram taken along a line D-D′ in FIG. 7. As shown in FIG. 7 and FIG. 8, the difference between the touch panel 400 in this embodiment and the touch panel in the first embodiment is that the touch panel 400 further includes a second insulation layer 250 disposed on the second axis electrodes 240Y. The second insulation layer 250 completely covers the second axis electrodes 240Y along the vertical projective direction Z, and the second axis electrodes 240Y are disposed between the second insulation layer 250 and the substrate 210. In other words, the second insulation layer 250 covers edges of each second axis electrode 240Y. In this embodiment, an outline of the second insulation layer 250 is the same as an outline of the second axis electrodes 240Y preferably, and a shape of the second insulation layer 250 is the same as a shape of the second axis electrodes 240Y preferably. The second insulation layer 250 encompasses the second axis electrodes 240Y. However, in other embodiments of the present invention, the second insulation layer 250 in other shapes may also be used to encompass the second axis electrodes 240Y. The second insulation layer 250 may include single layer or multiple layer structures formed by inorganic materials, such as silicon nitride, silicon oxide and silicon oxynitride, organic materials, such as acrylic resin, or other appropriate materials. In this embodiment, a refractive index of the second axis electrodes 240Y is higher than a refractive index of the second insulation layer 250 and the refractive index of the substrate 210 preferably so as to generate refractive index matching effect for lowering the pattern visibility of the second axis electrodes 240Y, but not limited thereto. Additionally, in other embodiments of the present invention, the first insulation layer 230 may at least partially overlap the second insulation layer 250 along the vertical projective direction Z so as to further lower the pattern visibility, but not limited thereto.

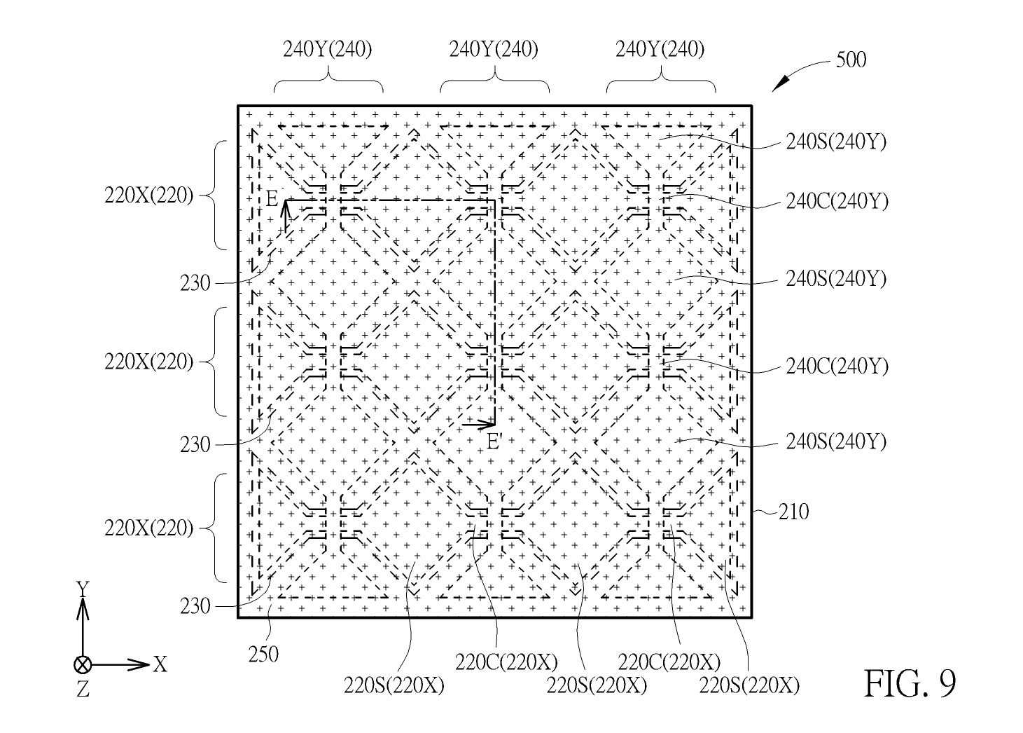

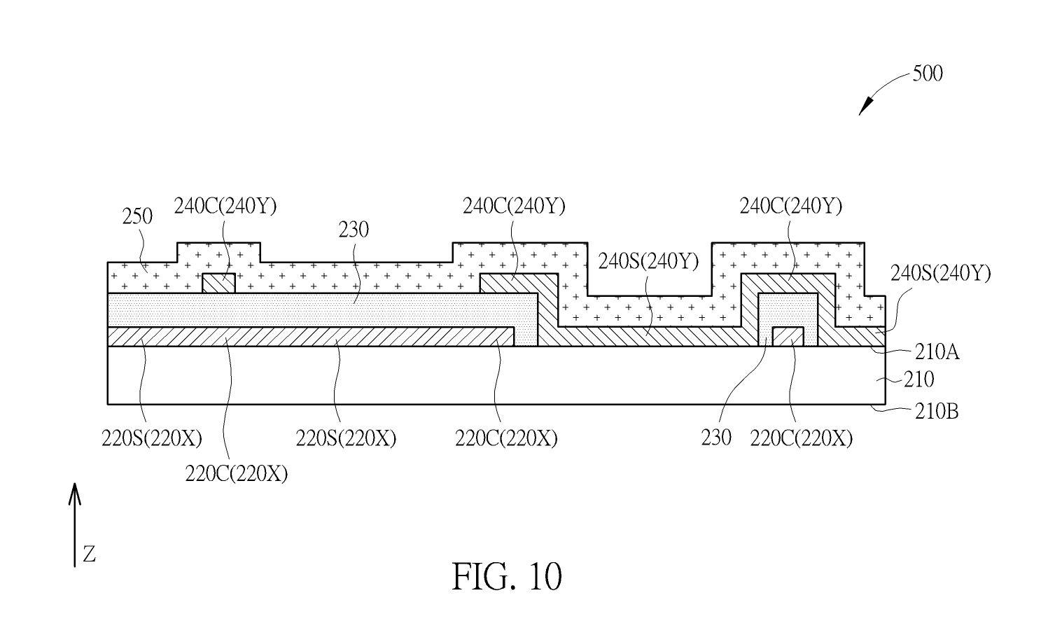

Please refer to FIG. 9 and FIG. 10. FIG. 9 is a schematic diagram illustrating a touch panel 500 according to a fourth embodiment of the present invention. FIG. 10 is a schematic cross-sectional diagram taken along a line E-E′ in FIG. 9. As shown in FIG. 9 and FIG. 10, the difference between the touch panel 500 in this embodiment and the touch panel in the third embodiment is that, in the touch panel 500, the second insulation layer 250 is one film layer with a full or complete surface covering the first axis electrodes 220X and the second axis electrodes 240Y so as to lower the pattern visibility of each first axis electrode 220X and each second axis electrode 240Y.

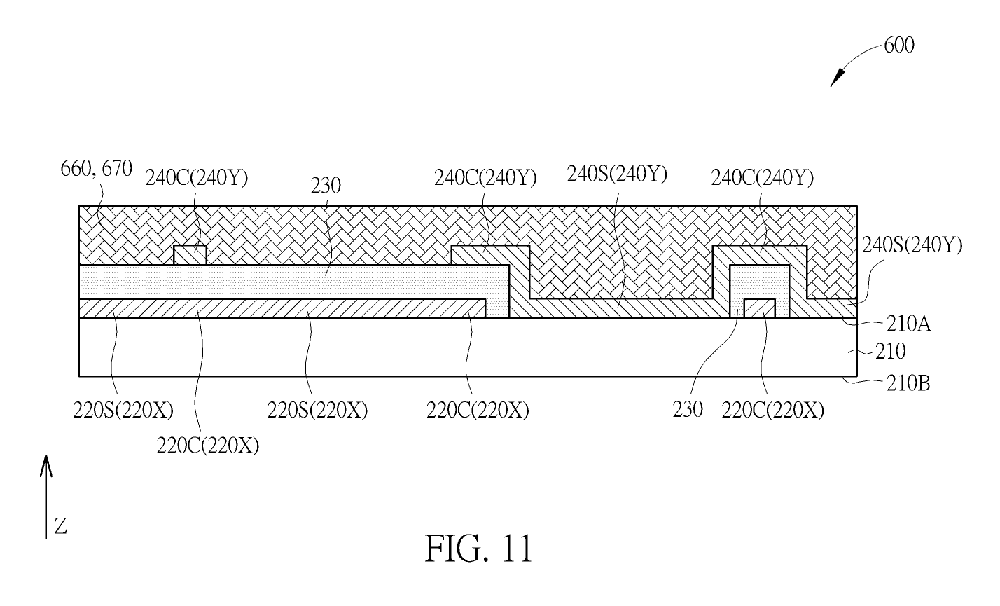

Please refer to FIG. 11. FIG. 11 is a schematic diagram illustrating a touch panel 600 according to a fifth embodiment of the present invention. As shown in FIG. 11, the difference between the touch panel 600 in this embodiment and the touch panel in the first embodiment is that the touch panel 600 further includes a protection layer 660 or an adhesion layer 670 covering the first axis electrodes 220X, the second axis electrodes 240Y and the first insulation layer 230. The protection layer 660 may include inorganic materials, such as silicon nitride, silicon oxide and silicon oxynitride, organic materials, such as acrylic resin, or other appropriate materials. The protection layer 660 is used to protect the first axis electrodes 220X and the second axis electrodes 240Y. A refractive index of the protection layer 660 is lower than the refractive index of the first insulation layer 230 preferably, and the refractive index of the first axis electrodes 220X is higher than the refractive index of the first insulation layer 230 preferably so as to generate refractive index matching effect for lowering the pattern visibility, but not limited thereto. For example, the refractive index of the protection layer 660 may also be higher than the refractive index of the first insulation layer 230. In addition, the adhesion layer 670 is used to adhere to another device such as a display panel, but not limited thereto. The adhesion layer 670 may include optical clear adhesive (OCA), pressure sensitive adhesive (PSA) or other appropriate adhesion materials preferably. A refractive index of the adhesion layer 670 is lower than the refractive index of the first insulation layer 230, and the refractive index of the first axis electrodes 220X is higher than the refractive index of the first insulation layer 230 preferably so as to generate refractive index matching effect for lowering the pattern visibility, but not limited thereto. It is worth noting that the protection layer 660 and/or the adhesion layer 670 in this embodiment may also be selectively applied to other embodiments of the present invention so as to the pattern visibility by adjust the index refraction matching conditions.

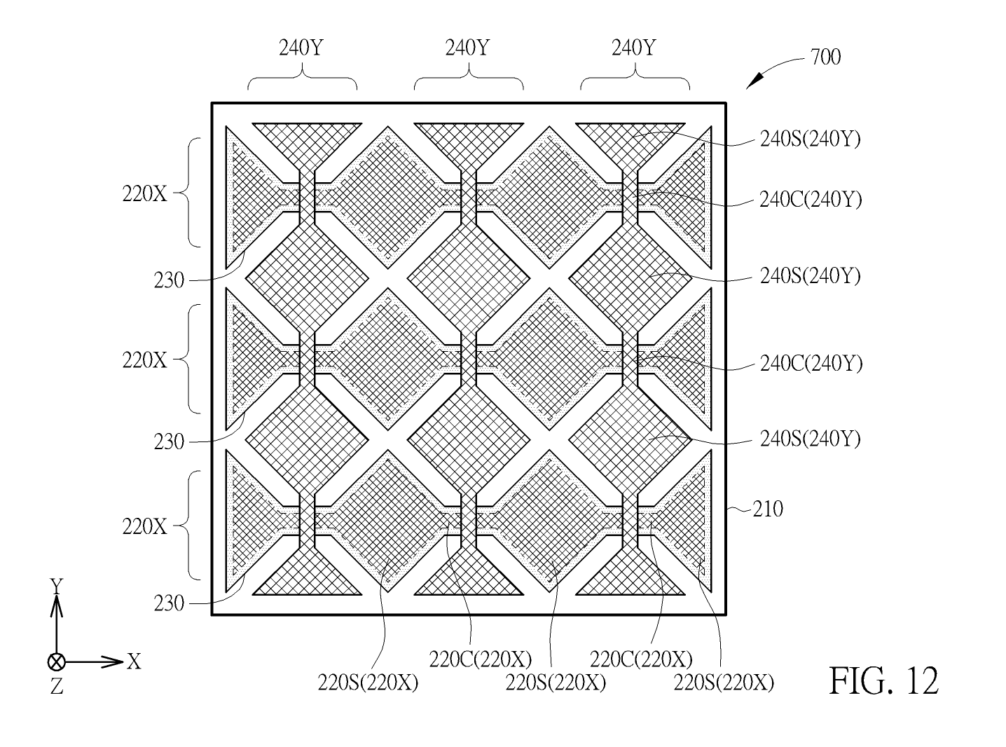

Please refer to FIG. 12. FIG. 12 is a schematic diagram illustrating a touch panel 700 according to a sixth embodiment of the present invention. As shown in FIG. 12, the difference between the touch panel 700 in this embodiment and the touch panel in the first embodiment is that, in the touch panel 700, the first axis electrodes 220X and the second axis electrodes 240Y are made of metal mesh. The metal mesh may include continuously stacked geometric figures in similar size or different shapes. The geometric figures of the metal mesh may include rhombus patterns, square patterns, rectangle patterns, hexagon patterns, other regular patterns or irregular patterns. Additionally, the metal mesh may also include a sine wave mesh pattern or other appropriate mesh patterns. It is worth noting that, in other embodiments mentioned above or below, the first axis electrodes 220X and the second axis electrodes 240Y may also be consisted of metal mesh. The first connection parts 220C and the first sub-electrodes 220S may then be formed monolithically without interface between the first connection parts 220C and the first sub-electrodes 220S, and the second connection parts 240C and the second sub-electrodes 240S may then be formed monolithically without interface between the second connection parts 240C and the second sub-electrodes 240S. The electrostatic discharge protection ability may be enhanced accordingly.

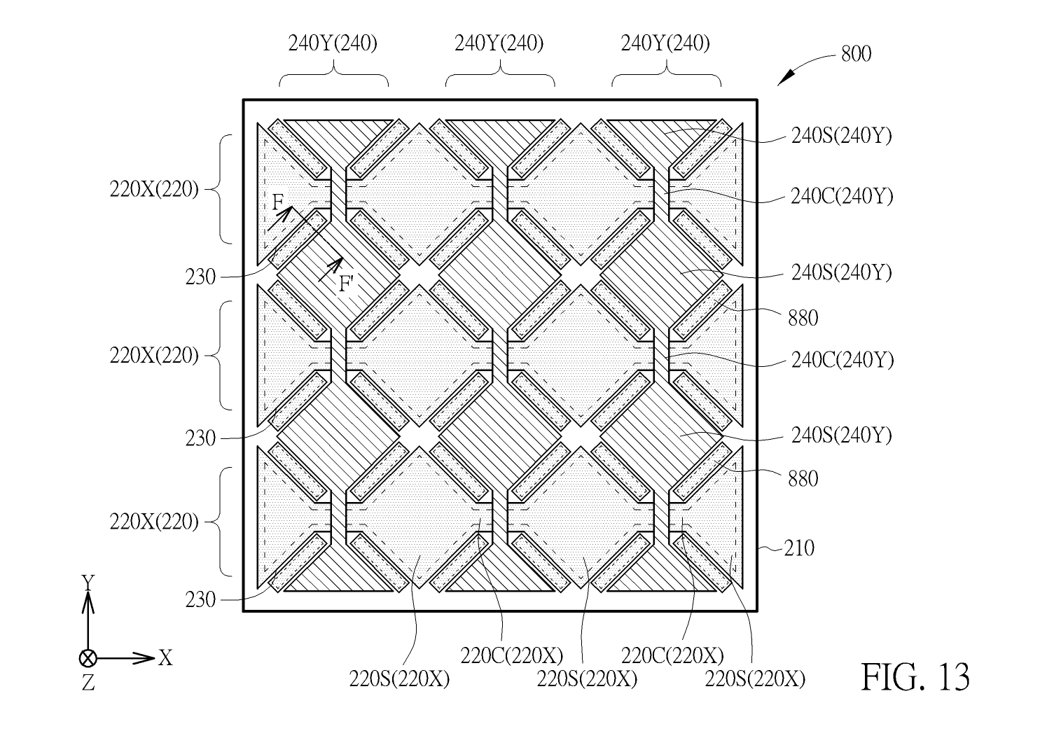

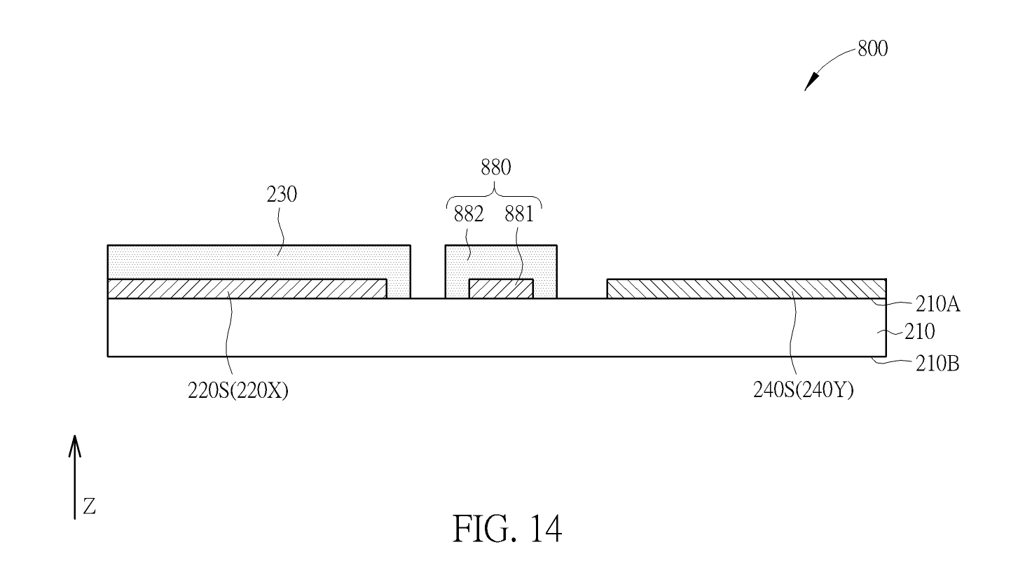

Please refer to FIG. 13 and FIG. 14. FIG. 13 is a schematic diagram illustrating a touch panel 800 according to a seventh embodiment of the present invention. FIG. 14 is a schematic cross-sectional diagram taken along a line F-F′ in FIG. 13. As shown in FIG. 13 and FIG. 14, the difference between the touch panel 800 in this embodiment and the touch panel in the first embodiment is that the touch panel 800 further includes a plurality of dummy patterns 880 disposed between each of the first sub-electrodes 220S and adjacent second sub-electrodes 240S. The dummy patterns 880 are electrically isolated from the first axis electrodes 220X and the second axis electrodes 240Y. The spacing between the first axis electrodes 220X and the second axis electrodes 240Y may be filled with the dummy patterns 880 so as to lower the pattern visibility of the first axis electrodes 220X and the second axis electrodes 240Y. Each of the dummy patterns 880 may include a conductive pattern 881 and an insulation pattern 882. The conductive pattern 881 is disposed between the insulation pattern 882 and the substrate 210. Specifically, the conductive pattern 881 and the first axis electrodes 220X may be formed by patterning one identical conductive layer, and the insulation pattern 882 and the first insulation layer 230 may be formed by one identical material, but not limited thereto. In other embodiments of the present invention, the conductive pattern 881 may also be formed by the manufacturing processes of the second axis electrodes 240Y, and the insulation pattern 882 may also be formed by the manufacturing processes of the second insulation layer (not shown in FIG. 13 and FIG. 14). Additionally, the shape and the amount of the dummy patterns 880 may be further modified according to other design considerations, and the dummy patterns 880 may also be applied in other embodiments mentioned above in the present invention so as to lower the pattern visibility of the first axis electrodes 220X and the second axis electrodes 240Y.

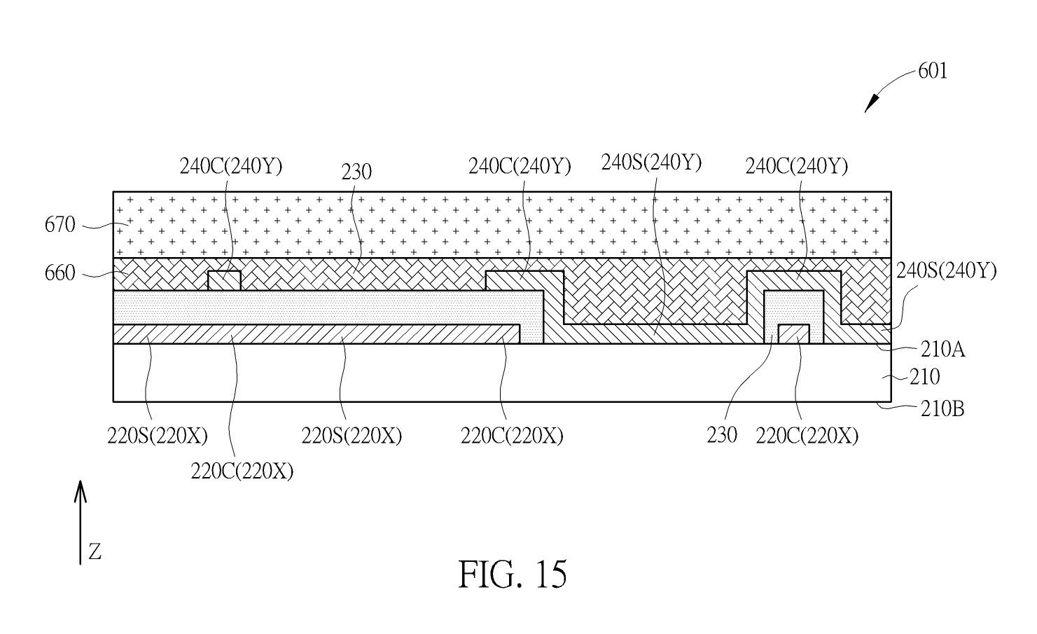

Please refer to FIG. 15. FIG. 15 is a schematic diagram illustrating a touch panel 601 according to an eighth embodiment of the present invention. As shown in FIG. 15, the difference between the touch panel 601 in this embodiment and the touch panel in the fifth embodiment is that the touch panel 601 includes both the protection layer 660 and the adhesion layer 670. The protection layer 660 and the adhesion layer 670 cover the first axis electrodes 220X, the second axis electrodes 240Y and the first insulation layer 230. The adhesion layer 670 is disposed on the protection layer 660 and covers the protection layer 660 preferably. The refractive index of the protection layer 660 is lower than the refractive index of the first insulation layer 230 preferably, and the refractive index of the first axis electrodes 220X is higher than the refractive index of the first insulation layer 230 preferably.

To summarize the above descriptions, in the touch panel of the present invention, each first axis electrode and each second axis electrode extend along different directions. Each of the first axis electrodes is monolithically formed, and each of the second axis electrodes are monolithically formed so as to enhance the electrostatic discharge protection ability of the first axis electrodes and the second axis electrodes. Additionally, the first insulation layer is used to completely cover the first axis electrodes and keep the first axis electrodes from being damaged by the manufacturing processes of the first insulation layer. The first sub-electrodes of the first axis electrodes and the second sub-electrodes of the second axis electrodes are disposed on one identical surface.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A touch panel, comprising:
a substrate;
a plurality of first axis electrodes, disposed on the substrate, wherein each of the first axis electrodes extends along a first direction, and each of the first axis electrodes comprises:
a plurality of first sub-electrodes; and
a plurality of first connection parts, disposed between two adjacent first sub-electrodes so as to electrically connect the first sub-electrodes, wherein each of the first connection parts and two adjacent first sub-electrodes are monolithically formed;
a plurality of second axis electrodes, disposed on the substrate, wherein each of the second axis electrodes extends along a second direction, the second direction crosses the first direction, and each of the second axis electrodes comprises:
a plurality of second sub-electrodes; and
a plurality of second connection parts, disposed between two adjacent second sub-electrodes so as to electrically connect the second sub-electrodes, wherein each of the second connection parts and two adjacent second sub-electrodes are monolithically formed, and the first sub-electrodes and the second sub-electrodes are disposed on an identical surface; and
a first insulation layer, disposed on the first axis electrodes and completely covering the first axis electrodes along a vertical projective direction perpendicular to the substrate, wherein the first insulation layer is partially disposed between each first connection part and each second connection part so as to electrically insulate the first axis electrodes from the second axis electrodes, and the first axis electrodes are disposed between the first insulation layer and the substrate.

2. The touch panel of claim 1, wherein an outline of the first insulation layer is the same as an outline of the first axis electrodes.

3. The touch panel of claim 1, wherein the first insulation layer has a plurality of openings, and each of the second sub-electrodes is disposed in one of the openings correspondingly.

4. The touch panel of claim 1, further comprising a second insulation layer, disposed on the second axis electrodes, wherein the second insulation layer completely covers the second axis electrodes along the vertical projective direction, and the second axis electrodes are disposed between the second insulation layer and the substrate.

5. The touch panel of claim 4, wherein an outline of the second insulation layer is the same as an outline of the second axis electrodes.

6. The touch panel of claim 4, wherein the second insulation layer is one film layer with a full surface covering the first axis electrodes and the second axis electrodes.

7. The touch panel of claim 1, wherein a refractive index of the first axis electrodes is higher than a refractive index of the first insulation layer.

8. The touch panel of claim 1, further comprising a protection layer covering the first axis electrodes, the second axis electrodes and the first insulation layer, wherein a refractive index of the protection layer is lower or higher than a refractive index of the first insulation layer, and a refractive index of the first axis electrodes is higher than the refractive index of the first insulation layer.

9. The touch panel of claim 1, further comprising an adhesion layer covering the first axis electrodes, the second axis electrodes and the first insulation layer, wherein a refractive index of the adhesion layer is lower than a refractive index of the first insulation layer, and a refractive index of the first axis electrodes is higher than the refractive index of the first insulation layer.

10. The touch panel of claim 1, further comprising a protection layer and an adhesion layer, the protection layer and the adhesion layer covering the first axis electrodes, the second axis electrodes and the first insulation layer, wherein a refractive index of the protection layer is lower or higher than a refractive index of the first insulation layer, a refractive index of the first axis electrodes is higher than the refractive index of the first insulation layer, and the adhesion layer covers the protection layer.

11. The touch panel of claim 1, wherein the first axis electrodes and the second axis electrodes comprises metal mesh consisted of a plurality of fine metal lines.

12. The touch panel of claim 1, further comprising a plurality of dummy patterns, disposed between each of the first sub-electrodes and adjacent second sub-electrodes, wherein the dummy patterns are electrically isolated from the first axis electrodes and the second axis electrodes.

13. The touch panel of claim 12, wherein each of the dummy patterns comprises a conductive pattern and an insulation pattern, and the conductive pattern is disposed between the insulation pattern and the substrate.

14. The touch panel of claim 1, wherein a width of each first sub-electrode along the second direction is wider than a width of each first connection part along the second direction, and a width of each second sub-electrode along the first direction is wider than a width of each second connection part along the first direction.
